(19) United States
(12) Patent Application Publication
(10) Pub. No.: US 2017/0003352 A1
(43) Pub. Date: Jan. 5, 2017

(54) METHOD, DEVICE AND SYSTEM FOR ESTIMATING THE STATE OF HEALTH OF A BATTERY IN AN ELECTRIC OR HYBRID VEHICLE DURING OPERATION THEREOF, AND METHOD FOR CREATING MODEL FOR ESTIMATION OF SAID TYPE

(71) Applicant: COMMISSARIAT A L'ENERGIE ATOMIQUE ET AUX ENERGIES ALTERNATIVES, Paris (FR)

(72) Inventors: Anthony BARRE, Combree (FR); Mathias GERARD, Grenbole (FR); Frédéric SUARD, Versailles (FR)

(21) Appl. No.: 15/106,776

(22) PCT Filed: Dec. 23, 2014
(86) PCT No.: PCT/EP2014/079230

§ 371 Date: Jun. 20, 2016

(30) Foreign Application Priority Data
Jan. 3, 2014 (FR) 1450025

(51) Int. Cl. G01R 31/36; G01R 31/00

(52) U.S. Cl. CPC G01R 31/3651; G01R 31/3675; G01R 31/007; G01R 31/3624

(57) ABSTRACT

A method for estimating the state of health of a battery of an electric or hybrid vehicle in conditions of use, comprises the following steps: a) during the operation of the battery, acquiring a time series of measurements of speed or of acceleration of the vehicle and, simultaneously, at least one time series of measurements of a quantity chosen from: a current or a power delivered by the battery, and a voltage at its terminals; b) extracting segments of the time series corresponding to speed or acceleration patterns that satisfy at least one predefined condition; and c) determining estimations of the state of health of the battery by application of at least one continuous estimation or classification model to the segments of the time series. A device and system for implementing such a method and a method for constructing a continuous estimation or classification model are provided.

The invention relates to a method, a device and a system for estimating the state of health of a battery of an electric or hybrid vehicle. The invention relates also to a method for constructing a model for estimating the state of health of such a battery.

The state of health, or level of aging, of a battery can be quantified by different variables. The most commonly used are the trends of capacity, of resistance or even of the impedance of the battery studied. An indicator normally employed is the SOH (State of Health), defined by:

$$\frac{nominal capacity at the time t}{initial capacity} \times 100 \%$$

As a variant, the SOH is sometimes defined from the resistance of the battery. Another indicator often used is the remaining useful life (RUL), which represents the proportion of time (or the number of cycles for example) remaining until an end of life EOL criterion, usually defined by a remaining capacity threshold, as a percentage. The RUL can also be called SOL (State of Life).

Whatever the parameter used to define it, the state of health of a battery must be known in real time by the user in order to avoid the risk of an untimely failure, or of an unexpected degradation of the performance levels of the appliance or machine powered by said battery. That is particularly important in the case of the batteries of electric or hybrid vehicles—and in particular cars. A direct calculation of the SOH by measurement of the capacity or of the resistance of the battery is possible in principle, but requires lengthy and complex measurements which cannot be implemented in real time. As for the RUL/SOL, it can only be estimated.

Because of the technical and economic importance of the problem, very many methods for estimating the state of health of a battery have been proposed. For a review of these methods reference can be made to the article by A. Barré et al. “A review on lithium-ion battery ageing mechanisms and estimations for automotive applications”, Journal of Power Sources 241 (2013) pages 680-689.

The problem of the estimation of the state of health (SOH) should be distinguished from that of the estimation of the state of charge (SOC). This second problem is simpler to resolve, because the voltage at the terminals of a battery charged to 100% exhibits a specific value which can serve as a reference. However, it is not generally possible to determine a level of aging by a simple voltage measurement. Among the known methods for estimating the SOC, the following can be cited:

the use of an RC equivalent circuit whose parameters are determined using an adaptive identification method, described for example by the article by Xiaosong Hu et al. “Estimation of State of Charge of a Lithium-Ion Battery Pack for Electric Vehicles Using an Adaptive Luenberger Observer”, Energies 2010, 3, 1586-1603;

a filtering method using a robust observable of H-infinity type, see for example US 2013/0300377.

Most of the existing solutions dealing with the problem of the estimation of the state of health of a battery in actual use, and in particular on an electric vehicle, use an equivalent circuit modeling the battery. The equivalent circuits differ from one proposal to another, according to the dynamics and the ranges of validity of these empirical models. In effect, the modeling of a battery by equivalent circuit is very difficult because of the complexity of the many physical-chemical phenomena involved in its aging. Also, this methodology is not sufficiently flexible, because the parameters of an equivalent circuit have to be adapted for each battery technology. Another major drawback with this methodology is that the model of estimation of the level of aging receives as input variables that require prior estimations. For example, the state of charge and the resistance of the battery must be either measured (which requires numerous specific tests) or estimated (which is a complex problem in itself). Thus, these variables induce biases from the very input of the model, which then provokes a divergence of the results in time. Finally, such models also prove to be not representative of the usages in real conditions because they are primarily based on tests in controlled conditions (test beds), which are not all meaningful of real uses.

As an example, it is possible to cite the article by B. Saha, K. Goebel, S. Poll and J. Christophersen “Prognostics methods for battery health monitoring using a bayesian framework”, IEEE Transactions on instrumentation and measurement 58 (2) (2009) 291-297. The method described in this article uses an evolving equivalent circuit, characterized by parameters whose values are estimated by electrochemical impedance spectroscopy measurements. Aging curves representing the trend of these parameters are determined “offline” by relevance vector regression, or relevance vector machine (RVM); then, the evolving model that is thus developed is used in a dynamic state estimation process, of PF (particle filter) type.

Other methods for estimating the state of health of a battery known from the prior art use mappings of aging defined during prior tests; see for example the document FR2975188. These mappings associate, for example, a measured resistance with a prediction of the capacity of the battery, or else use a measured maximum voltage and a temperature for estimating a state of health. This methodology cannot be adapted to real conditions. In effect, in order to be representative of the real conditions, a mapping would have to take into account all the parameters that might be involved in the aging phenomena. Now, these are too numerous and interdependent to be effectively taken into account, which induces a lack of reliability of the estimations obtained in this way.

The physical modeling approach is also widely used in the issues associated with the estimation of the aging of the batteries; see for example US20130030739. It consists in determining equations modeling the trend of the state of health of a battery. These equations are determined to be in agreement with data obtained on a test bed, but prove ill-suited to modeling in real conditions, because the degradation phenomena are very complex and originate from numerous interdependent parameters, which leads to a very difficult modeling. Furthermore, these methods are not applicable on line because the calculations required are too complex for the power of the embedded computers.

Yet other methods use learning methods such as neural networks and/or fuzzy logic based on signals and estimated parameters. See for example the document US 2010/0324848. These methods can be used online; their main disadvantages are linked to the use of data obtained on a test bed.

The invention aims to overcome, wholly or partly, at least some of the abovementioned drawbacks of the prior art. More particularly, the invention aims to allow for an estimation that is reliable and “online” (that is to say during use) of the state of health of a battery of an electric or hybrid vehicle.

One subject of the invention that makes it possible to achieve this aim is a method for estimating the state of health of a battery of an electric or hybrid vehicle in conditions of use, comprising the following steps:

a) during the operation of said battery, acquiring a time series of measurements of speed or of acceleration of said vehicle and, simultaneously, at least one time series of measurements of a quantity chosen from: a current or a power delivered by said battery, and a voltage at its terminals;

b) extracting segments of said time series corresponding to speed or acceleration patterns that satisfy at least one predefined condition; and

c) determining estimations of the state of health of said battery by application of at least one continuous estimation or classification model to said segments of said time series.

According to different embodiments of the invention:

said step a) can also comprise the simultaneous acquisition of a time series of measurements of temperature of said battery; said step b) can also comprise the extraction of segments of said time series of temperature measurements corresponding to said speed or acceleration patterns; and said step c) can comprise the application of said or each said continuous estimation or classification model also to said segments of said time series of temperature measurements, or to a mean temperature value associated with each said segment.

During said step b), a segment of said time series of speed or acceleration measurements can be considered to satisfy said predefined condition when a variation of speed or of acceleration, respectively, lying within a first predefined range occurs in a time interval lying within a second predefined range.

Said step c) can comprise an operation of readjustment of said segments of said time series of measurements, prior to the application of said or each said continuous estimation or classification model, said readjustment operation comprising, for each said speed pattern: the identification of a transformation converting said speed pattern into a reference speed pattern; and the application of said transformation, or of a transformation which is associated with it, to each said segment of said time series corresponding to said speed pattern.

Said or at least one said continuous estimation or classification model can be based on a metric or pseudo-metric chosen from: a pseudo-metric of dynamic time warping; and a metric of overall alignment.

Said or at least one said continuous estimation or classification model can be a kernel model.

The method can also comprise a step d) of updating of said continuous estimation or classification model or models, or of a posteriori correction of said estimations, from estimations of the state of health of said battery obtained by offline characterization.

Another subject of the invention is a device for estimating the state of health of a battery of an electric or hybrid vehicle in conditions of use, comprising:

at least one first input port for a signal indicative of a speed or of an acceleration of said vehicle;

at least one second input port for a signal indicative of a current or of a power delivered by said battery, or of a voltage at its terminals; and

a data processing module configured or programmed to implement a method as mentioned above by using said signals.

Yet another subject of the invention is a system for estimating the state of health of a battery of an electric or hybrid vehicle in conditions of use, comprising:

such a device;

at least one sensor of speed or acceleration of a vehicle, linked to said first port of said device; and

at least one current or voltage sensor, linked to said second port of said device.

Yet another subject of the invention is a method for constructing a model for estimating the state of health of a battery of an electric or hybrid vehicle in conditions of use, comprising the following steps:

A) over a plurality of periods of operation of said battery, acquiring a time series of measurements of speed or of acceleration of said vehicle and, simultaneously, at least one time series of measurements of a quantity chosen from: a current or a power delivered by said battery, and a voltage at its terminals;

B) extracting segments of said time series corresponding to speed or acceleration patterns that satisfy at least one predefined condition;

C) determining reference states of health of said battery during said periods of operation by interpolation of estimations of said state of health obtained by means of offline characterization performed between said periods of operation; and

D) constructing at least one continuous estimation or classification model from said segments of said time series and from the corresponding reference states of health.

According to particular embodiments of such a method:

said step A) can also comprise the simultaneous acquisition of a time series of measurements of temperature of said battery; said step B) can also comprise the extraction of segments of said time series of temperature measurements corresponding to said speed or acceleration patterns; and said step D) can comprise the construction of said continuous estimation or classification model also from said segments of said time series of temperature measurements, or from a mean temperature value associated with each said segment.

During said step B), a segment of said time series of speed or acceleration measurements can be considered to satisfy said predefined condition when a variation of speed or of acceleration, respectively, lying within a first predefined range occurs in a time interval lying within a second predefined range.

Said step D) can comprise an operation of readjustment of said segments of said time series of measurements, prior to the construction of said or each said continuous estimation or classification model, said readjustment operation comprising, for each said speed pattern: the identification of a transformation converting said speed pattern into a reference speed pattern; and the application of said transformation, or of a transformation which is associated with it, to each said segment of said time series corresponding to said speed pattern.

Said or at least one said continuous estimation or classification model can be based on a metric or pseudo-metric chosen from: a pseudo-metric of dynamic time warping; and a metric of overall alignment.

Said or at least one said continuous estimation or classification model can be a kernel model.

Other features, details and advantages of the invention will emerge on reading the description given with reference to the attached drawings given by way of example and which represent, respectively:

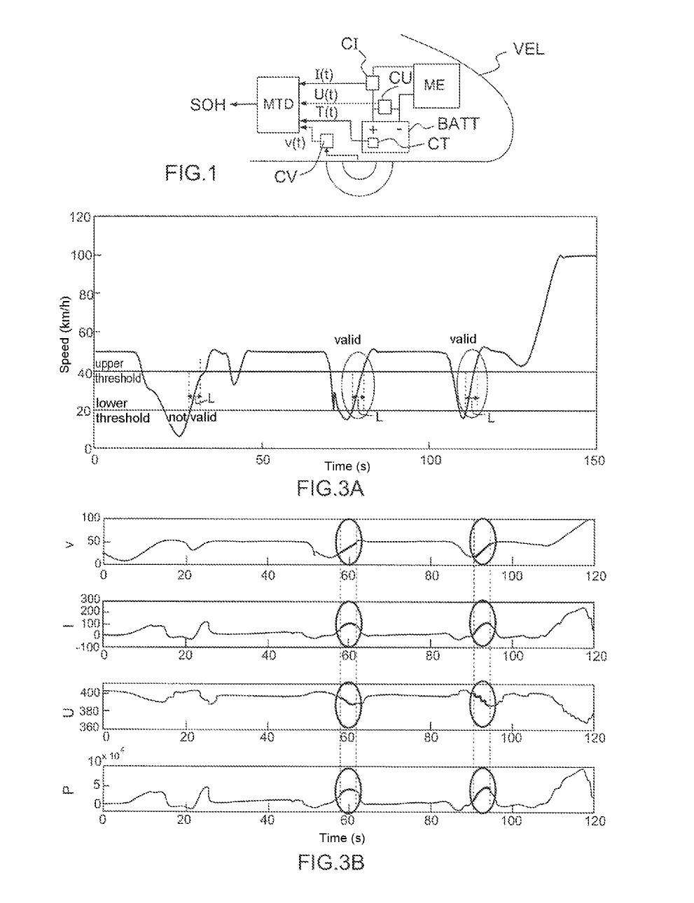

FIG. 1, a functional diagram of a system for estimating the state of health of a battery of an electric or hybrid vehicle according to an embodiment of the invention;

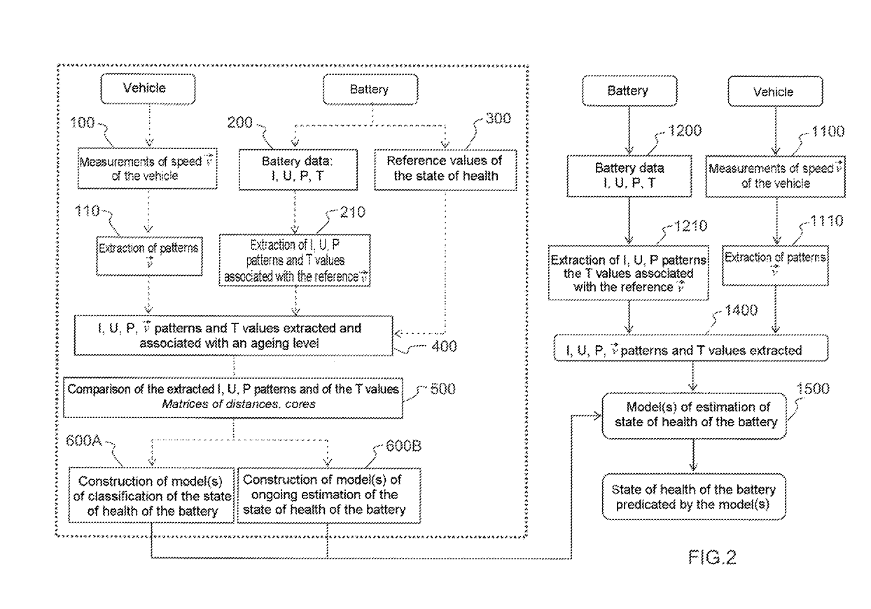

FIG. 2, a flow diagram of a method for estimating the state of health of a battery of an electric or hybrid vehicle and of a method for constructing a model for such an estimation according to two embodiments of the invention;

FIGS. 3A and 3B, a step of extraction of segments of time series of measurements corresponding to vehicle speed patterns that satisfy a predefined condition, according to an embodiment of the invention;

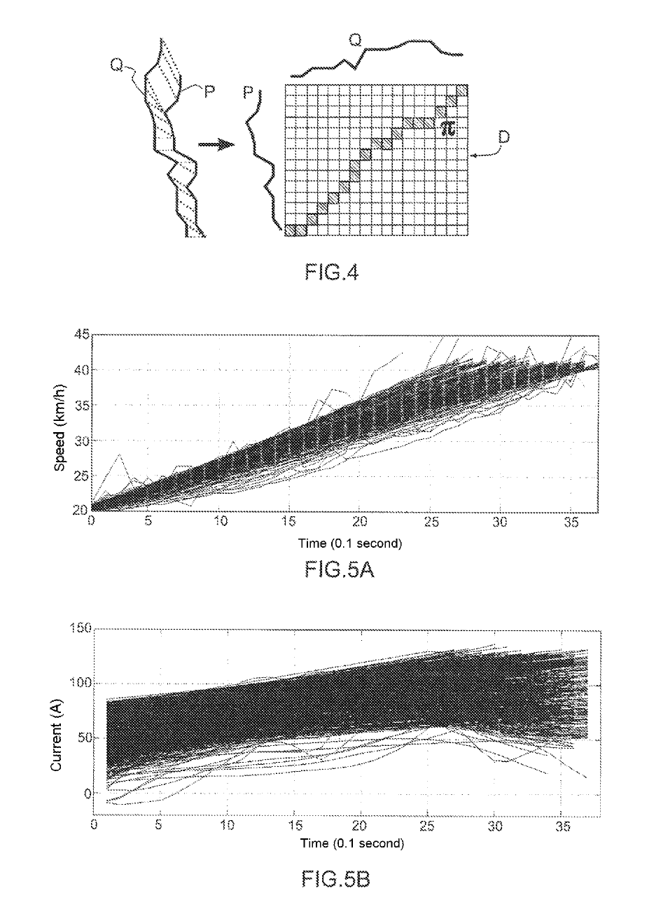

FIG. 4, the pseudo-metric of dynamic time warping (DTW), used in an advantageous embodiment of the invention;

FIGS. 5A and 5B, segments of time series of speed and current measurements obtained during the implementation of a method according to an embodiment of the invention;

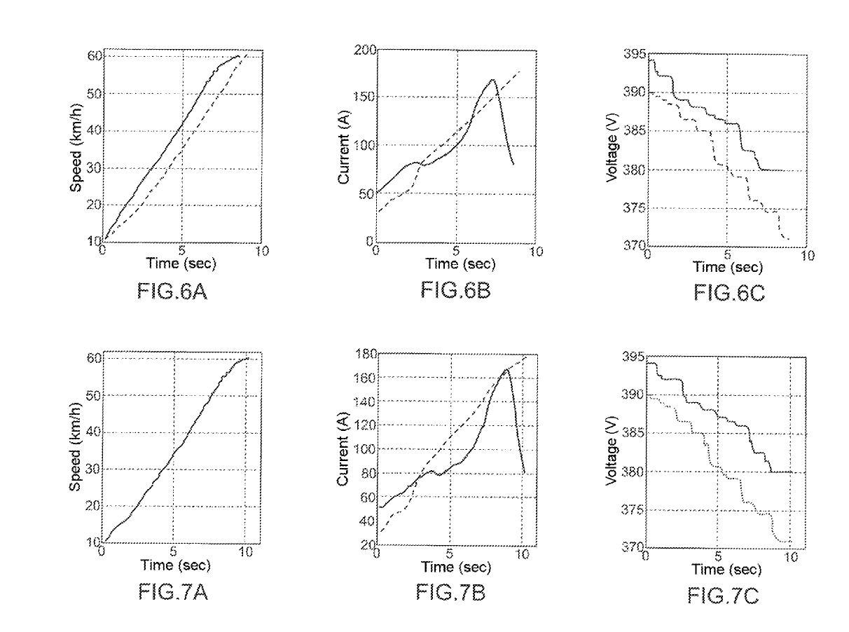

FIGS. 6A, 6B, 6C and 7A, 7B, 7C, graphs illustrating a readjustment operation (optional); and

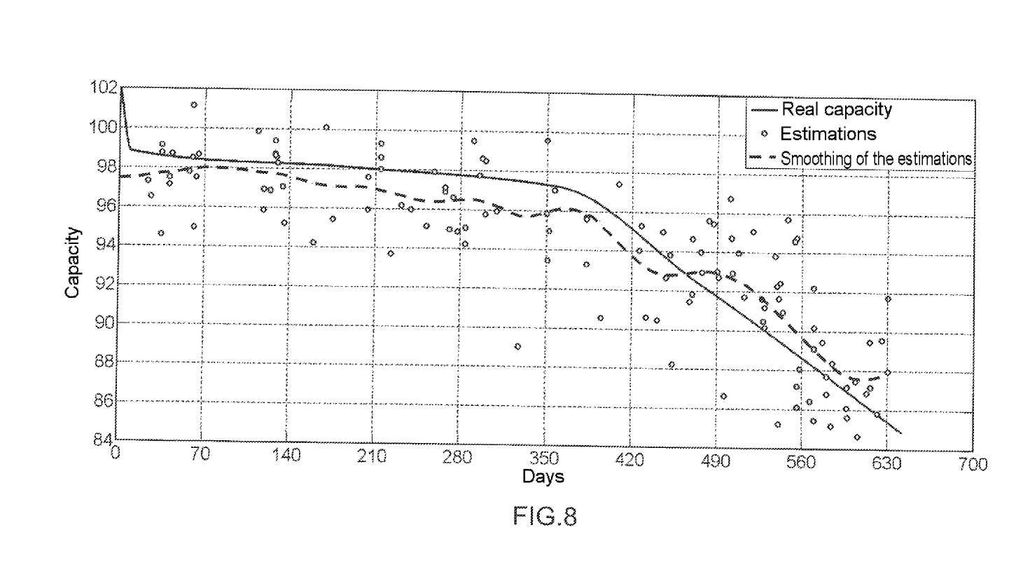

FIG. 8, the results of an continuous estimation of the state of health of a battery obtained by implementing a method according to an embodiment of the invention.

FIG. 1 represents an electric battery BATT embedded in an electric or hybrid land vehicle VEL, powering an electric motor ME and connected to a system for estimating its state of health according to an embodiment of the invention. This system, also embedded, comprises a data processing module MTD and a plurality of sensors, and in particular: a voltage sensor CU for measuring the voltage U(t) at the terminals of the battery; a current sensor CI for measuring a current I(t) supplied (or absorbed) by the battery, a temperature sensor CT for measuring an internal temperature T(t) of the battery and a speed sensor CV measuring the instantaneous speed v(t) of the vehicle. Other sensors may also be present, notably other temperature sensors for measuring temperatures at different points of the battery or of its environment. Conversely, the temperature sensor CT and/or one of the two sensors CU, CI (but not both at the same time) may be omitted. The speed sensor can be replaced or accompanied by a vehicle acceleration sensor, or any other sensor measuring a parameter characteristic of a state of motion thereof. The data processing module MTD receives as input the signals generated by these sensors and supplies as output an estimation of the state of health of the battery (indicated “SOH” in the figure, but it can be any parameter indicative of such a state of health, such as the RUL for example).

This module can notably comprise by a processor appropriately programmed, accompanied by a memory storing one or more programs for the implementation of a method according to the invention, parameters of one or more models for estimating the state of health of the battery and, possibly, time series of measurements from said sensors (which is useful for the offline construction and/or updating of the models). It can also comprise one or more other signal processing circuits, analog or digital.

The data processing module MTD, and all or some of the sensors CI, CU, CT and Cv, can form part of a battery management system (BMS).

As will be explained in detail hereinbelow, the construction of the model or models for estimating the state of health of the battery is made by using both the signals from the sensors CI, CU, CT, Cv and the results of “offline” characterizations of the battery. This construction can be performed by the data processing module MTD (which must then receive the abovementioned results as input) or by an external computer, interfaced with the MTD module.

According to the invention, the state of health of the battery BATT is estimated directly from signals from the battery and from the vehicle, obtained via sensors CI, CU, CT, Cv. FIG. 2 illustrates:

in its left hand part, a method for constructing a model for estimating the state of health of the battery BATT; and

in its right hand part, a method for estimating the state of health of the battery BATT from this model.

These two methods constitute two aspects of the present invention. They both use the signals generated by the sensors CI, CU, CT, Cv during the real operation of the battery and of the vehicle. The method for constructing the estimation model also uses reference values of the state of health of the battery, obtained by “offline” characterization. The method for estimating the state of health, by contrast, is performed entirely “online” or in “real time”.

The various steps of these two methods will now be described with reference, when necessary, to FIGS. 31, 3B and 4.

### I. Construction of the Model or Models for Estimating the State of Health of the Battery (Left Hand Part of FIG. 2)

The construction of the model or models for estimating the state of health of the battery comprises the following steps: the obtaining, in real time, of data relating to the battery (current and/or voltage and/or power, possibly temperature, etc.) and to the vehicle (speed and/or acceleration), the extraction of reference speed patterns, and of current and/or voltage and/or power patterns and of temperature values corresponding to these patterns; the correlation of these patterns with reference values of the state of health of the battery, obtained by interpolation of measurements performed offline; the comparison of the extracted patterns, preceded or accompanied by a possible readjustment; and finally said actual construction of models for the continuous or discrete (classification) estimation of the state of health of the battery.

i. Obtaining of the Battery and Vehicle Data—Blocks 100, 200 and 300 of the Flow Diagram of FIG. 2

This first step consists in directly collecting data from the batteries and vehicles studied. These batteries (or just one) need to have been used for a fairly long time to obtain complete and diverse data. The referent criterion is the end of life (EOL) of the battery, usually defined, in the case of electric vehicles, as the moment when a battery reaches 80% of its nominal initial capacity. During this phase, the batteries must be instrumented to then allow for the constant acquisition of data during use (block 200), which will then be able to be used in the invention. These values can be the temperature T of the batteries, the voltage U at their terminals, the current delivered I and the power delivered P (the latter being able to be obtained from voltage and current measurements: P=U·I).

The other variable extracted during use is the speed (and/or the acceleration) of the vehicles. All these acquisitions are done in the course of tests (block 100). It is sufficient to have at least one of the signals I, U, P to establish a predictive model; however, it is also possible to take into account a number of these signals (I, U or I, P or U, P or I, U, P). The information on the temperature of each of the batteries can also be added as additional information, but is not necessary to the implementation of the process.

With the models being constructed in a decentralized context, the data are retained, for example in a memory of the processing module MTD, to be processed at the end of the process of data acquisitions from real tests. This then makes it possible to perform the calculations by means of a computer other than the BMS (battery management system) which acquires the data.

Also, it is necessary for the methodology to have state-of-health references in order to construct the models. These references must be obtained periodically during trials (block 300). This can be done through complete characterizations of the batteries studied or of the vehicle (tests on roller bed) or else by other methods: offload voltage, etc. These tests make it possible to obtain battery aging parameters, for example the maximum capacity or else the value of the resistance of the battery at the instants of the characterizations. These values serve as an aging reference for the construction of the models. An interpolation (linear, cubic, etc.) makes it possible to obtain a continuous trend of these state-of-health values of the battery. The “time” axis can be the trial time or else the energy delivered, even the distance depending on the variables obtained during the tests. Continuous state-of-health trends are thus obtained for each of the batteries having been studied in this process.

Thus, there are, in this context, three different types of data dependent on one another:
data from the batteries during use: instantaneous current I, and/or voltage U and/or power P and possibly temperature T;
data from the vehicles during runs: \vec{v};
trend of the reference of the state of health of each of the batteries.

Hereinbelow, S will be used to denote all the signals from the battery. Thus, S contains at least one signal out of (I, U and P) and can also contain temperature information T. By convention, the plural will be used with regard to the set S, although the latter may comprise only a single signal (I or U or P).

ii. Extraction of the Reference \vec{v} Patterns—Block 110

One idea on which the present invention is based consists in comparing the differences between signals from the battery over time in order to predict the aging undergone by the battery. For this, it is necessary to take a comparison criterion, in order to quantify the modification of the signals over time for identical or similar uses. Another idea on which the invention is based consists in extracting, from the time series of measurements from the sensors, repetitive patterns serving as a reference for the comparisons made subsequently. These comparisons will be established in order to identify the differences in behavior of the signals according to the corresponding aging level at that instant.

The signal which serves as a reference is the speed of the vehicle (in other embodiments, it could be the acceleration). To precede with the extraction of repetitive patterns, certain criteria have to be set in order to proceed with this detection automatically. In the case of a speed signal, the extraction criteria can be length of the pattern, as well as the lower and upper speed thresholds. In this case, for a speed pattern to be selected, a variation of speed lying within a first predefined range must occur in a time interval lying within a second predefined range. In the example of FIG. 3A, a variation of speed of at least 20 km/h between a low speed of 20 km/h and a high speed of 40 km/h (first range) is required to occur within a time not greater than 2.5 seconds and not less than 3.7 seconds (second range); the bottom limit of this range could be set to zero (all the “rapid” accelerations are considered), but a non-zero lower limit is useful to avoid taking account of the signals from measurement errors. In the example of FIG. 3A, a vehicle runs at a cruising speed of 50 km/h and undergoes five periods of deceleration followed by an acceleration which returns it to the cruising speed; then it accelerates to a new cruising speed of 100 km/h. Only the acceleration phases are considered (which is not an essential limitation). The first acceleration phase is discarded because the variation from 20 km/h to 40 km/h occurs within a time greater than the upper limit of the second range; the second and the fifth acceleration phases, and the last acceleration which brings the vehicle to a speed of 100 km/h are discarded because the speed does not cross the lower threshold of 20 km/h. By contrast, the third and the fourth acceleration phases satisfy the criterion indicated above.

The level set for the thresholds delimiting the speed variation range has a significant influence on the sensitivity and the accuracy of the method. Thus, a high upper speed threshold will result in a low number of patterns being saved, which may result in a less powerful model because of the lack of data. On the contrary, the choice of an excessively narrow variation range will lead to the extraction of a large number of patterns, but the latter will be too short to contain meaningful information on the state of health of the battery being studied. Furthermore, the amplitude of the speed variation range can be chosen in accordance with the data acquisition frequency. Thereby, a low acquisition frequency induces a wide speed variation range in order to be able to identify dynamics in the signals. One possible criterion consists in considering a limit length of 20 values per segment extracted, which represents, for example, a segment of 2 seconds for an acquisition frequency of 10 Hz.

Since the aim of this extraction is to characterize phenomena linked to the aging of a battery, the pattern is preferentially matched to a strong braking, or else to a strong acceleration.

Criteria other than that mentioned above can be used for the selection of the patterns; for example, the acceleration of the vehicle may be required to exceed a predefined threshold.

iii. Extraction of the Time Series of Measurements Corresponding to the Speed Patterns—Block 210

Following the process of extraction of the patterns of the reference variable (speed, even acceleration), it is necessary to extract segments corresponding to said patterns from the time series of signals S from the battery. In other words, the information on the time location of the extracted reference patterns, in the complete signals \vec{v} is used in order to obtain segments or patterns of the set S (depending on the variables taken into account) associated with the reference patterns (speeds). This step is illustrated in FIG. 3B, which shows the extraction of segments of time series of current (I), voltage (U) and power (P) corresponding to the two speed patterns identified during the preceding step.

If the temperature T of the battery is used, only its mean value correlated with the extracted speed patterns need be retained. In effect, the temperature has a slow dynamic compared to the other variables.

At the end of this step, there are n speed profiles, associated with n segments of time series of measurements of each variable considered (I and/or U and/or P), and optionally n mean temperature T values. It is important to keep the information on placements in the trial time, and on the corresponding battery.

iv. Taking Account of the Aging Level—Block 400

Next, each of the duly extracted segments of S is associated with one or more state-of-health references (capacity, impedance, etc.), previously determined and stored (step I.i and block 300 in FIG. 2). The end result is thus n sets of data each containing:
a reference \vec{v} pattern;
at least one segment of a time series of measurements S chosen from I, U and P, and optionally a value T; and
at least one reference for the state of health of the battery corresponding to the segment (s) of S and to the reference \vec{v} pattern.

v. Comparison of the Extracted Segments, Construction of Distance Matrixes and, if Necessary, of Kernels—Block 500

The aim of this step is to study the modification of the extracted profiles, according to the level of aging of the battery, in order to construct state-of-health estimation models. However, it is essential to consider that these patterns of variables are sensitive to the alterations in the reference \vec{v} pattern. In effect, to be able to ideally compare the extracted segments, it would be necessary to have exactly the same reference patterns (speeds), derived from the same conditions (temperature, level of charge, wind, driver, etc.). In such a case, the modifications perceived in the segments of S would be only due to the aging phenomena. Now, obtaining exactly identical conditions is unfeasible in the context of real in-use data. It is therefore useful to use a methodology that takes account of the modifications of the reference patterns.

To do this, a readjustment may be considered by applying appropriate transformations to the reference \vec{v} patterns, so as to make them identical to one another, then applying these same transformations—or corresponding transformations—to the associated segments of S. Such a readjustment method can then be performed by wavelet methods, or by readjustment derived from dynamic time warping (DTW) or else by simple interpolation of the signals.

The principle of dynamic time warping will now be illustrated using FIG. 4.

Let P=(p₁, . . . , p_{N}) and Q=(q₁, . . . , q_{M}) be two time series of lengths N and M. If N≠M, these two series cannot be compared by a simple Euclidian distance. The dynamic time warping (DTW) makes it possible to contract and expand the time axis, mitigating the alignment problems. The principle of the DTW metric (in fact, it is a pseudo-metric) consists in constructing a cost matrix D (N×M), with a measurement φ(pᵢ, qⱼ), often defined as the Euclidian distance (pᵢ, qᵢ)=∥pᵢ−qⱼ∥², then in finding, from the set of possible alignments A(N,M), the alignment π which minimizes the aggregate costs between P and Q. An alignment π is of length |π|=L, and is made up of L-tuples (π₁,π₂), such that:

1=π₁(1)≦ . . . ≦π₁(L)=N

1=π₂(1)≦ . . . ≦π₂(L)=M

Thus, the DTW distance is defined between two signals P and Q by:

$$DTW ( P , Q ) := {min}_{π ∈ A ( N , M )} {D}_{P , Q} ( π )$$

with:

$${D}_{P , Q} := {\sum }_{i = 1}^{\vert π \vert} φ ( {p}_{{π}_{1}} ( i ) , {q}_{{π}_{2}} ( i ) )$$

As mentioned above, DTW(P,Q) is not strictly a metric (it is called “pseudo-metric”) because it does not satisfy the triangular identity:

DTW(P,R)≮DTW(P,Q)+DTW(Q,R),∀P,Q,R

If the difference in length between the time series is not too great (less than a factor 2), it is possible to use a global alignment (GA) metric. A GA distance takes account of all the costs D_{P,Q}(π), πε [symbol] (n,m)}; more specifically, the global alignment distance k_{GA} is given by

$${k}_{GA} ( x , y ) := {\sum }_{π ∈ A ( n , m )} exp ( - {D}_{x , y} ( π ) ) .$$

Another possibility consists in not modifying the extracted signals and using a suitable comparison system that takes account of this problem. It is then a matter of considering the signals as they have been extracted, and of comparing them from a (pseudo-) metric taking account of the time differences (for example, DTW).

The readjustment by DTW will now be illustrated with the help of an example.

Consider a set S1 of signals (V₁,I₁,U₁) (solid line in FIGS. 6A, 6B and 6C) and another set S2 of signals (V₂,I₂,U₂) (dotted line), each of these two sets originating from the same speed extraction criteria (10-60 km/h between 7 and 10 seconds). A readjustment by DTW is then performed on the signals V₁ and V₂, in other words the transformation π described above is sought. To recap, this transformation (or alignment) correlates the vectors V₁ and V₂ by time warping. The process then consists in keeping this time warping to apply it directly to I and U. The result of this method can be seen in FIGS. 7A, 7B and 7C.

Whatever the option chosen, it is necessary to apply one or more (pseudo-) metrics, in order to quantify the differences between extracted segments. The choice of a metric has to make it possible to take account of the initial modifications due to the data recording conditions. The Euclidian distance can be used in the case of segments of identical length (which is improbable in the context of real use). Other metrics such as the Manhattan distance [Mattausch02], or else the “Complexity Invariant Distance” [Batista11] can be employed. Other possibilities, that do not require the segments to be of identical length, are the distance derived from the DTW [Keogh05] or else the cross correlation between signals [Hirata08], for example.

The particular advantage of the distance coming from the DTW is that it can be applied whatever the length or the form of the segments. Furthermore, this method makes it possible to calculate the difference between two segments by taking account of the time distortions. The latter can, in the case studied here, be due to the fluctuations of the recording conditions (temperature, rain, wind, driving, etc.). Consequently, the use of the DTW seems particularly suited to resolving the problems associated with changing conditions.

Each of these metrics provides a value representing the difference between two extracted segments. It is then possible to apply one or more of these metrics to obtain a matrix or matrices of dissimilarity between each of the extracted segments. These matrices, quantifying the different segments in different ways, will be employed in the subsequent construction of the models.

Finally, in the context of the constructions of models by statistical methods, a choice can be made to calculate one or more kernel(s) from the metrics calculated previously, or else directly from the segments.

The kernels used can be directly derived from a scalar product. For example, the following can be cited in a nonlimiting manner:
Triangular kernel: K(u)=(1−|u|)1_{{|u|≦1};}
Gaussian kernel:

$$K ( u ) = \frac{1}{\sqrt{2 π}} {e}^{- \frac{1}{2} {u}^{2}} ;$$

Epanechnikov kernel: K(u)=(1−|u|)1_{{|u|≦1}.}
   u corresponding to a distance between signals.

Kernels calculated from the DTW can also be considered. For example, the following can be cited in a nonlimiting manner:
Gaussien DTW kernel (GDTW) [Lei08];
Negative DTW (NDTW) [Gudmundsson08];
“Softmax” DTW kernel [De Vries12];
Gaussian elastic metric kernel (GEMK) [Zhang10].

Finally, kernels inspired by DTW can also be calculated, such as those derived from the global alignment (GA) approach. For example, the following can be cited in a nonlimiting manner:
Global alignment kernel (GAK) [Cuturi06];
“log GA” kernel [Cuturi11];
Triangular GAK kernel (TGAK) [Joder08].

The kernels directly derived from the DTW are not, strictly speaking, defined positive, although they are more often than not in the application cases, because the DTW is not a metric, but a pseudo-metric. This feature is the reason for the GA approach which tries to resolve this drawback. A quick overview of the various kernels is given in the article [Joder08].

Each of these kernels requires, for its construction, parameters, to be set beforehand, for example by cross-validation, which is a method well known in statistics. Consideration can obviously be given to also employing another type of kernel subsequently. Furthermore, the values of T, if they have been taken into account, can be compared by a kernel declining from the Euclidian distance.

At the end of this step, there are therefore n sets of data (S, \vec{v}, aging) created during the preceding step as well as matrices of distance between the extracted segments of S and possibly one or more kernels calculated for each variable (U and/or I and/or P and/or T). All such information can be used to construct models for estimating the state of health of a battery simply from at least one pattern extracted from S and one associated reference \vec{v} pattern.

vi. Construction of the Models—Block 600A and/or 600B

All the necessary information extracted by the preceding steps forms a reference base. The last step of this part then consists in constructing models that take as input segments of S, and, optionally, a value T, associated with a reference pattern, and which have for output an estimation of state of health of the corresponding battery. The output can be discrete or continuous depending on the type of method used in the model construction.

### 600A: Discrete Classification Model

The objective of the classification models is to predict a state-of-health class for a new signal. Thus, the result of this type of model is not continuous, but discrete. Numerous algorithms are suited to this type of problem. The state-of-health classes can be intervals, regular or not, of values. The important thing being that all the values are contained in one and the same class.

A non-exhaustive list of the methodologies closest to the problem dealt with is given below:
k-Plus closest neighbors (k-PPV): For a new segment of S supplied as input, this method determines the k segments closest thereto, from the distance taken into account during the preceding step, (from a distance matrix or from a kernel), and attributes the new segment to the majority class out of the k neighbors. The only parameter to be chosen is the number of neighbors k chosen [Hastie01, p 463-468].
kMeans: This method forms k clusters of segments taken as references, each associated with the majority state-of-health class. The methodology of this algorithm is described in the literature [Hastie01, p. 460-461]. Thus, for a new segment, its class attributed will be that of the closest cluster. This notion can be defined by the minimum mean distance between the segment to be classified and all the segments of a cluster, or else by the distance between the segment to be classified and the centroid of the segments of a cluster.
Hierarchical classification: In the same way as the kMeans method, this method divides a sample of reference segments into k clusters. The methodology consists here in building a hierarchical tree from the distances calculated during the preceding step. From this hierarchical tree, the algorithm consists in pruning the latter in order to form k clusters of segments. Once these clusters are formed, the diagnostic process is identical to that explained for the kMeans method [Hastie01, p. 520-525].
Support vector machine (SVM): This supervised learning method, contrary to the preceding ones, requires a prior construction of kernel(s). Furthermore, it is the only one that can create a model constructed over several segments derived from S, and also over one or more kernel(s) calculated from the values of T. For this, the kernels of the reference patterns are then associated (multiple kernel learning, or MKL), as is detailed in [Gonen11]. Also, the complete operating process of the SVM method is also described in numerous articles such as [Hastie01, p. 423-431]. This method allows for the more accurate detection of the modifications due to the changing states of health of the battery than that which is supplied by the other methods explained.

### 600A: Continuous Estimation Models

The methodology used in the context of the continuous estimation of the state of health of a battery is primarily based on the kernel(s) constructed during the preceding step. Because of this, if no kernel has been calculated during this step, the continuous estimation will be done primarily according to regression methods.

The methods envisaged for producing a continuous estimation of the state of health of a battery are, for example:
Regression methods: Regression algorithms, based on “shrinkage”, such as the LASSO method [Hastie01, p. 68-69], the Ridge method [Hastie01, p. 61-64], or even the LARS method [Efron03].
Support vector regression (SVR): This method is an extension of the SVMs allowing for a continuous output. The process is detailed in the literature
[Smola03]. As in the case of the SVMs, it is possible to take into account a number of kernels, derived from the comparison of the segments of S extracted and from the values of T.
Relevance vector machine (RVM): This is the most standard kernel method in the continuous output problems. The principle is explained amply in [Tipping01]. In the same way as all the kernel methods, the implementation of this method requires a choice in the values of the parameters.
Kernel ridge regression: An alternative of ridge regression consists in using kernels in this method, as detailed in [Welling].

### II. Diagnostic of a Battery in Real Use (Right-Hand Part of FIG. 2)

This part deals with the application of the models constructed in part I., in a context of real use of a battery on an electric or hybrid vehicle. The aim is to manage to do a diagnosis of the state of health of the battery, without any particular usage requirement.

The process for estimating the state of health of the battery uses many steps described in part I. Thus, the application also requires a battery and a vehicle that are instrumented, allowing for the real time acquisition of the same data as in part I.i. (I and/or U, and/or P; optionally T; \vec{v})—see the blocks 1200 and 1100 in the right hand part of FIG. 2. Furthermore, the estimation model(s) constructed during the step I.vi. are here introduced into the methodology in the form of decision functions of input-output type.

The processing of the data obtained from the battery consists, initially, in extracting, in the course of the acquisitions, speed patterns corresponding to the criteria set in section I.ii. (blocks 1110 and 1220).

Subsequently, as soon as a speed pattern has been extracted (block 1400), it can be used—with the corresponding time series segments of S—for the estimation of the state of health of the battery by application of one or more models constructed during the step I.vi (block 1500). For that, the same process as that described in I.ii. to I.iv. is applied, thus making it possible to obtain a signal I, U and/or P corresponding to the extracted speed pattern (because that is done in real time during the acquisitions). If necessary, a readjustment is also applied, as in the construction of the models.

In the case of a use of a single model, the response obtained on the state of health of the battery directly provides the estimation. By contrast, if a number of models are used, as many estimations are obtained. Thus, the user can choose to consider all the estimations (display of all the results which then forms a confidence interval), or else take into account all the values in order to calculate a state-of-health diagnosis from the estimators. That may consist, among other things, in calculating a mean, a median, a selection of the near values, or else prioritizing a method.

It is important to note that the method is implemented during the use of an electric vehicle and in real conditions. In effect, the diagnostics are provided as soon as a reference speed pattern has been detected, which is why the definition thereof is very important (thresholds and length of the pattern). The estimations are therefore supplied immediately after the extraction of an appropriate speed pattern. In effect, once the model construction steps I. have ended, the calculation times are compatible with embedded use.

The models for estimating the state of health of the battery can be updated. For that, it is necessary to obtain one or more new exact aging values, derived from specific tests. That can then be performed during tests during a run of the vehicle in a specialist garage.

Two possibilities then allow for the update: either the construction of new models with these data, or a correction of the bias of the estimations made. The first option consists in reconstructing new models by the process explained in the steps I.; that therefore requires an offline calculation step. In the second case, it simply involves applying a correction to the estimations made in order to correct the measured bias. In other words, if the last estimation made predicts a resistance of 0.8 and the specifically measured exact value is 0.81, then a correction of “+1.25%” will be applied to the new estimations.

The technical result of the invention will now be illustrated, by considering a specific example of implementation, using FIGS. 5A and 5B.

The criteria chosen for the extraction of the speed patterns are then an acceleration from 20 to 40 km/h between 2.5 and 3.7 seconds, which corresponds to FIGS. 3A and 3B discussed above. The patterns obtained (FIG. 5A) illustrate the problem linked to the offsets due to the outside conditions. Only the current signals will be considered here in order to make an estimation of battery capacity. These signals I corresponding to the speed patterns are presented in FIG. 5B.

From these data—and from the reference values of the state of health of the battery—two models are developed in order to predict a capacity level related to the initial capacity (SOE indicator): a discrete model derived from the kNN method by DTW distance, another from the SVM method employing log GAK kernels.

In the case of the kNN method, a cross-validation makes it possible to set the number of closest neighbors (in terms of DTW distance) at 24. The following four classes are considered: C1=[100%-96.75%], C2=[96.75%-93.50%], C3=[93.50%-90.25%], C4=[90.25%-87%]. The results of the method are illustrated by a confusion matrix, showing the percentages of good classifications, for an overall accuracy (percentage of signals whose classification is exact) of 59%:

Predicted class

| | | C1 | C2 | C3 | C4 |
|---|---|---|---|---|---|
| Real class | C1 | 55.1% | 28.6% | 12.2% | 4.1% |
| | C2 | 36.7% | 40.9% | 16.3% | 6.1% |
| | C3 | 19% | 4.8% | 66.7% | 9.5% |
| | C4 | 6% | 8% | 12% | 74% |

An SVM classification was also performed on these same data, by considering two classes C1′=[100%-93.50%] and C2′=[93.50%-87%]. The SVM method also requires parameters to be set automatically by cross-validation, and more specifically a soft margin parameter C and a parameter A conditioning the associated quadratic programming (QP) method. The results then allow for an overall classification accuracy of 80%. The confusion matrix is:

Predicted class

| | | C1′ | C2′ |
|---|---|---|---|
| Real class | C1′ | 74.4% | 25.6% |
| | C2′ | 15.1% | 84.9% |

Thus, these two methods provide two classes as a result. The choice made in terms of decision is then to take the means of the limits of these classes in the case where the results are different. Because of this, when the results of the estimations at a given instant are respectively C2=[96.75%-93.50%], and C2′=[93.50%-87%], the interval [95.125%, 90.25%] will be retained.

A model of continuous estimation by RVM with a DTWK kernel was also tested by using the patterns I and U derived from accelerations between 10 and 60 km/h in a time lying between 7 and 10 seconds. The results are illustrated in FIG. 8.

### REFERENCES

[Batista11] G. E. A. P. A. Batista, X. Wang, E. Keogh, A complexity invariant distance measure for time series, Proceedings of the Eleventh SIAM International Conference on Data Mining, SDM 2011, Apr. 28-30, 2011, Mesa, Ariz., USA.
[Cuturi06] M. Cuturi, J. P. Vert, O. Birkenes, T. Matsui, A kernel for time series based on global alignments, Acoustics, Speech and Signal Processing, 2007. ICASSP 2007, IEEE International Conference on. Vol. 2. IEEE, 2007.
[Cuturi11] M. Cuturi, Fast Global Alignment Kernels, Proceedings of the International Conference on Machine Learning (ICML-11) (2011).
[De Vries12] G. K. D. De Vries, Kernel methods for vessel trajectories (2012) p.45-66.
[Efron03] B. Efron, T. Hastie, I. Johnstone, R. Tibshirani, Least angle regression, Ann.Statist. Volume 32, Number 2 (2004), 407-499.
[Gonen11] M Gönen, E Alpaydin, Multiple kernel learning algorithms, Journal of Machine Learning Research, 999999 (2011): 2211-2268 [Gudmundsson08] S. Gudmundsson, T. P. Runarsson, S. Sigurdsson, Support Vector Machines and Dynamic Time Warping for Time Series, Neural Networks, 2008. IJCNN 2008.(IEEE World Congress on Computational Intelligence). IEEE International Joint Conference on. IEEE, 2008.
[Hastie01] T. Hastie, R. Tibshirani, J. Friedman, The elements of statistical learning, Vol. 2. New York: Springer (2001), p.59-64, 377-384, 412-417, 472-479.
[Hirata08] S. Hirata, M. K. Kurosawa, T. Katagiri, Cross-correlation by single-bit signal processing for ultrasonic distance measurement, IEICE Transactions on Fundamentals of Electronics, Communications and Computer Sciences 91.4 (2008): 1031-1037.
[Joder08] C. Joder, S. Essid, G. Richard, Alignment kernels for audio classification with application to music instrument recognition, European Signal Processing Conference (EUSIPCO 2008), Lausanne, Switzerland, 2008.
[Keogh05] E. Keogh, C. A. Ratanamahatana, Exact indexing of dynamic time warping, Knowledge and Information Systems (7) (2005) 358_386.
[Lei08] H. Lei, V. Govindaraju, A Study on the Dynamic Time Warping in Kernel Machines, Signal-Image Technologies and Internet-Based System, 2007. SITIS '07. Third International IEEE Conference on (p. 839-845).
[Mattausch02] H. J. Mattausch, N. Omori, S. Fukae, T. Koide, T. Gyoten, Fully-parallel pattern-matching engine with dynamic adaptability to Hamming or Manhattan distance, VLSI Circuits Digest of Technical Papers 2002. Symposium on, IEEE (2002).
[Smola03] A. J. Smola, B. Schölkopf, A tutorial on support vector regression, Statistics and computing, —14(3): 199-222.
[Tipping01] M. E. Tipping, Sparse bayesian learning and the relevance vector machine, J. Mach. Learn. Res. 1 (2001) 211_244.
[Welling] M. Welling, Kernel ridge regression Department of Computer Science, University of Toronto, Toronto (Kanada).
[Zhang10] D. Zhang, W. Zuo, D. Zhang, H. Zhang, Time series classification using support vector machine with Gaussian elastic metric kernel, Proceedings of International Conference on Pattern Recognition (2010) IEEE (pp. 29-32).

1. A method for estimating the state of health of a battery of an electric or hybrid vehicle in conditions of use, comprising the following steps:
a) during the operation of said battery, acquiring a time series of measurements of speed or of acceleration of said vehicle and, simultaneously, at least one time series of measurements of a quantity chosen from: a current or a power delivered by said battery, and a voltage at its terminals;
b) extracting segments of said time series corresponding to speed or acceleration patterns that satisfy at least one predefined condition; and
c) determining estimations of the state of health of said battery by application of at least one continuous estimation or classification model to said segments of said time series.

2. The method of claim 1, wherein:
said step a) also comprises the simultaneous acquisition of a time series of measurements of temperature of said battery;
said step b) also comprises the extraction of segments of said time series of temperature measurements corresponding to said speed or acceleration patterns; and
said step c) comprises the application of said or each said continuous estimation or classification model also to said segments of said time series of temperature measurements, or to a mean temperature value associated with each said segment.

3. The method of claim 1, wherein, during said step b), a segment of said time series of speed or acceleration measurements satisfies said predefined condition when a variation of speed or of acceleration, respectively, lying within a first predefined range, occurs in a time interval lying within a second predefined range.

4. The method of claim 1, wherein said step c) comprises an operation of readjustment of said segments of said time series of measurements, prior to the application of said or each said continuous estimation or classification model, said readjustment operation comprising, for each said speed pattern:
the identification of a transformation converting said speed pattern into a reference speed pattern; and
the application of said transformation, or of a transformation which is associated with it, to each said segment of said time series corresponding to said speed pattern.

5. The method of claim 1, wherein said or at least one said continuous estimation or classification model is based on a metric or pseudo-metric chosen from:
a pseudo-metric of dynamic time warping; and
a metric of overall alignment.

6. The method of claim 1, wherein said or at least one said continuous estimation or classification model is a kernel model.

7. The method of claim 1, also comprising a step d) of updating of said continuous estimation or classification model or models, or of a posteriori correction of said estimations, from estimations of the state of health of said battery obtained by offline characterization.

8. A device for estimating the state of health of a battery of an electric or hybrid vehicle in conditions of use, comprising:
at least one first input port for a signal f indicative of a speed or of an acceleration of said vehicle;
at least one second input port for a signal indicative of a current or of a power delivered by said battery, or of a voltage at its terminals; and
a data processing module configured or programmed to implement a method as claimed in one of the preceding claims by using said signals.

9. A system for estimating the state of health of a battery of an electric or hybrid vehicle in conditions of use, comprising:
a device of claim 8;
at least one sensor of speed or acceleration of a vehicle, linked to said first port of said device; and
at least one current or voltage sensor, linked to said second port of said device.

10. A method for constructing a model for estimating the state of health of a battery of an electric or hybrid vehicle in conditions of use, comprising the following steps:
A) over a plurality of periods of operation of said battery, acquiring a time series of measurements of speed (v) or of acceleration of said vehicle and, simultaneously, at least one time series of measurements of a quantity chosen from: a current or a power delivered by said battery, and a voltage at its terminals;
B) extracting segments of said time series corresponding to speed or acceleration patterns that satisfy at least one predefined condition;
C) determining reference states of health of said battery during said periods of operation by interpolation of estimations of said state of health obtained by means of offline characterization performed between said periods of operation; and
D) constructing at least one continuous estimation or classification model from said segments of said time series and from the corresponding reference states of health.

11. The method of claim 10, wherein:
said step A) also comprises the simultaneous acquisition of a time series of measurements of temperature (T) of said battery;
said step B) also comprises the extraction of segments of said time series of temperature measurements corresponding to said speed or acceleration patterns; and
said step D) comprises the construction of said continuous estimation or classification model also from said segments of said time series of temperature measurements, or from a mean temperature value associated with each said segment.

12. The method of claim 10, wherein, during said step B), a segment of said time series of speed or acceleration measurements satisfies said predefined condition when a variation of speed or of acceleration, respectively, lying within a first predefined range occurs in a time interval lying within a second predefined range.

13. The method of claim 10, wherein said step D) comprises an operation of readjustment of said segments of said time series of measurements, prior to the construction of said or each said continuous estimation or classification model, said readjustment operation comprising, for each said speed pattern:
the identification of a transformation converting said speed pattern into a reference speed pattern; and
the application of said transformation or of a transformation which is associated with it, to each said segment of said time series corresponding to said speed pattern.

14. The method of claim 10, wherein said or at least one said continuous estimation or classification model is based on a metric or pseudo-metric chosen from:
a pseudo-metric of dynamic time warping; and
a metric of overall alignment.

15. The method of claim 10, wherein said or at least one said continuous estimation or classification model is a kernel model.
